(19) United States
(12) Patent Application Publication
(10) Pub. No.: US 2025/0253096 A1
(43) Pub. Date: Aug. 7, 2025

(54) CAPACITOR DEVICE

(71) Applicant: SAMSUNG ELECTRONICS CO., LTD., Suwon-si (KR)

(72) Inventors: Yoonjae Lee, Suwon-si (KR); Byungjoon Yoo, Suwon-si (KR); Yongjun Kim, Suwon-si (KR); Sangwan Nam, Suwon-si (KR)

(21) Appl. No.: 18/938,023

(22) Filed: Nov. 5, 2024

(30) Foreign Application Priority Data
Feb. 2, 2024 (KR) 10-2024-0016905

(51) Int. Cl. H01G 4/01; H01G 4/008; H01G 4/228; H01G 4/38

(52) U.S. Cl. CPC H01G 4/01; H01G 4/228; H01G 4/38; H01G 4/008

(57) ABSTRACT

A capacitor structure includes a substrate, a first lower wiring layer and a second lower wiring layer on the substrate, a plurality of first electrodes on the substrate, a plurality of second electrodes on the substrate and alternately arranged with the plurality of first electrodes, and a first upper wiring layer and a second upper wiring layer at a vertical level that is different from a vertical level of the first lower wiring layer and the second lower wiring layer, the first upper wiring layer and the second upper wiring layer being electrically insulated from each other. The first lower wiring layer is electrically connected to the first upper wiring layer through the plurality of first electrodes and the second lower wiring layer is electrically connected to the second upper wiring layer through the plurality of second electrodes.

### CROSS-REFERENCE TO RELATED APPLICATION

This application claims priority to Korean Patent Application No. 10-2024-0016905, filed in the Korean Intellectual Property Office on Feb. 2, 2024, the disclosure of which is incorporated by reference herein in its entirety.

### BACKGROUND

Generally, capacitors store charge and supply charge necessary for the operation of semiconductor devices. With the development of high-capacity and high-density semiconductor devices, the size of memory cells rapidly is decreasing and an area that can be occupied by a cell capacitor in a memory cell is also rapidly decreasing. To secure at least a certain amount of capacitance in a small area, a three-dimensional structure, in which electrode structures extend in a vertical direction in parallel with each other, is used for capacitors to increase the area of an electrode. However, as the size of memory cells decreases due to the high integration density of semiconductor devices, it is difficult to increase capacitance per unit area of a capacitor.

### SUMMARY

In general, in some aspects, the present disclosure is directed toward a capacitor device capable of increasing capacitance per unit area and improving electrical characteristics.

According to some implementations, the present disclosure is directed to a capacitor device including a substrate, a first lower wiring layer and a second lower wiring layer on the substrate, a plurality of first electrodes on the substrate, a plurality of second electrodes on the substrate and alternately arranged with the plurality of first electrodes, and a first upper wiring layer and a second upper wiring layer at a vertical level that is different from a vertical level of the first lower wiring layer and the second lower wiring layer, wherein the first lower wiring layer is electrically connected to the first upper wiring layer through the plurality of first electrodes, the second lower wiring layer is electrically connected to the second upper wiring layer through the plurality of second electrodes, and the first lower wiring layer faces the second lower wiring layer with the plurality of first electrodes and the plurality of second electrodes between the first lower wiring layer and the second lower wiring layer.

According to some implementations, the present disclosure is directed to a capacitor device including a first lower wiring layer and a second lower wiring layer, each extending in one direction, a first upper wiring layer and a second upper wiring layer respectively apart from the first lower wiring layer and the second lower wiring layer in a vertical direction, a plurality of first electrodes each including a first base portion and a first pad portion, the first base portion being between the first lower wiring layer and the second lower wiring layer and extending in the vertical direction, and the first pad portion protruding from the first base portion toward the first upper wiring layer, and a plurality of second electrodes each including a second base portion and a second pad portion, the second base portion being between the first lower wiring layer and the second lower wiring layer and extending in the vertical direction, and the second pad portion protruding from the second base portion toward the second upper wiring layer, wherein the first lower wiring layer is electrically connected to the first upper wiring layer through the plurality of first electrodes between the first lower wiring layer and the first upper wiring layer, and the second lower wiring layer is electrically connected to the second upper wiring layer through the plurality of second electrodes between the second lower wiring layer and the second upper wiring layer.

According to some implementations, the present disclosure is directed to a capacitor device including a lower capacitor structure and an upper capacitor structure. The lower capacitor structure includes a first lower wiring layer and a second lower wiring layer apart from each other and extending in one direction, a first upper wiring layer and a second upper wiring layer respectively apart from the first lower wiring layer and the second lower wiring layer in a vertical direction, the first upper wiring layer and the second upper wiring layer being apart from each other and extending in the one direction, a plurality of first electrodes electrically connected to the first lower wiring layer and the first upper wiring layer, and a plurality of second electrodes electrically connected to the second lower wiring layer and the second upper wiring layer and alternately arranged with the plurality of first electrodes in the one direction. The upper capacitor structure includes a first lower interlayer wiring layer and a second lower interlayer wiring layer apart from each other and extending in the one direction on the lower capacitor structure, a first upper interlayer wiring layer and a second upper interlayer wiring layer respectively apart from the first lower interlayer wiring layer and the second lower interlayer wiring layer in the vertical direction, the first upper interlayer wiring layer and the second upper interlayer wiring layer being apart from each other and extending in the one direction, a plurality of third electrodes electrically connected to the first lower interlayer wiring layer and the first upper interlayer wiring layer, and a plurality of fourth electrodes electrically connected to the second lower interlayer wiring layer and the second upper interlayer wiring layer and alternately arranged with the plurality of third electrodes in the one direction, and an interlayer insulating film between the lower capacitor structure and the upper capacitor structure. Each of the plurality of first electrodes has one sidewall and the other sidewall opposite the one side wall, the first lower wiring layer faces the one sidewall of each of the plurality of first electrodes, and the first upper wiring layer faces the other sidewall of each of the plurality of first electrodes.

### BRIEF DESCRIPTION OF THE DRAWINGS

Example implementations will be more clearly understood from the following detailed description, taken in conjunction with the accompanying drawings.

FIG. 1 is a perspective view of an example of a capacitor device according to some implementations.

FIG. 2A is a layout diagram of the capacitor device at an example of a first level LV1 in FIG. 1 according to some implementations.

FIG. 2B is a layout diagram of the capacitor structure at an example of a second level LV2 in FIG. 1 according to some implementations.

FIG. 3A is a cross-sectional view taken along line A1-A1′ in FIGS. 2A and 2B according to some implementations.

FIG. 3B is a cross-sectional view taken along line A2-A2′ in FIGS. 2A and 2B according to some implementations.

FIG. 4A is a cross-sectional view taken along line B1-B1′in FIGS. 2A and 2B according to some implementations.

FIG. 4B is a cross-sectional view taken along line B2-B2′ in FIGS. 2A and 2B according to some implementations.

FIG. 5A is a diagram illustrating an example of a capacitor device according to some implementations.

FIG. 5B is a diagram illustrating an example of a capacitor device according to some implementations.

FIG. 6A is a diagram illustrating an example of a capacitor device according to some implementations.

FIG. 6B is a diagram illustrating an example of a capacitor device according to some implementations

FIG. 7A is a diagram illustrating an example of a capacitor device according to some implementations.

FIG. 7B is a diagram illustrating an example of a capacitor device according to some implementations.

FIG. 8 is a diagram illustrating an example of a capacitor device according to some implementations.

FIG. 9 is a diagram illustrating an example of a capacitor device according to some implementations.

FIG. 10 is a diagram illustrating an example of an operation of a semiconductor device according to some implementations.

### DETAILED DESCRIPTION

Hereinafter, example implementations will be explained in detail with reference to the accompanying drawings. In the drawings, like numerals denote like elements and redundant descriptions thereof will be omitted.

Herein, a horizontal direction may include a first horizontal direction (an X direction) and a second horizontal direction (a Y direction), which cross each other. A direction that crosses the first horizontal direction (the X direction) and the second horizontal direction (the Y direction) may be referred to as a vertical direction (a Z direction). Herein, a vertical level may be referred to as a height level of any configuration in the vertical direction (the Z direction).

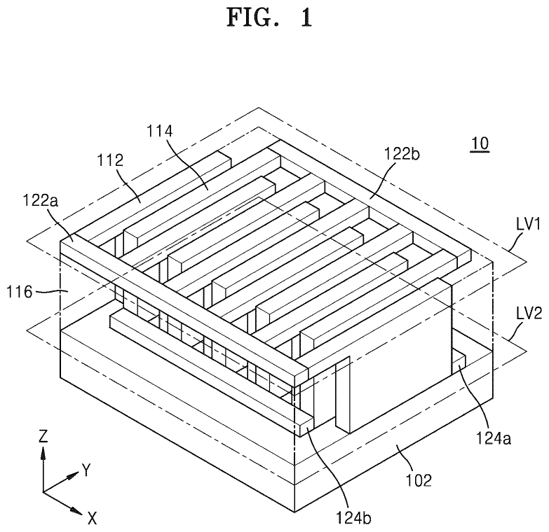

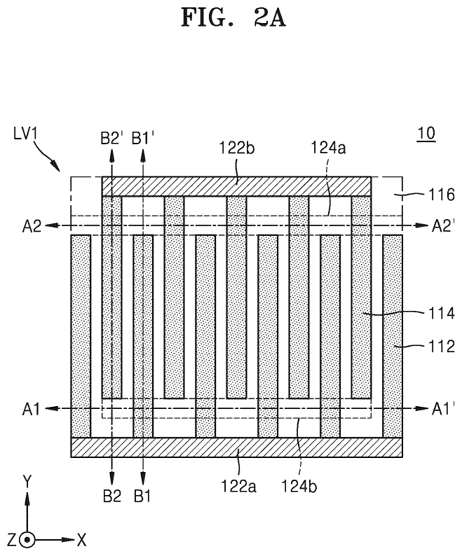

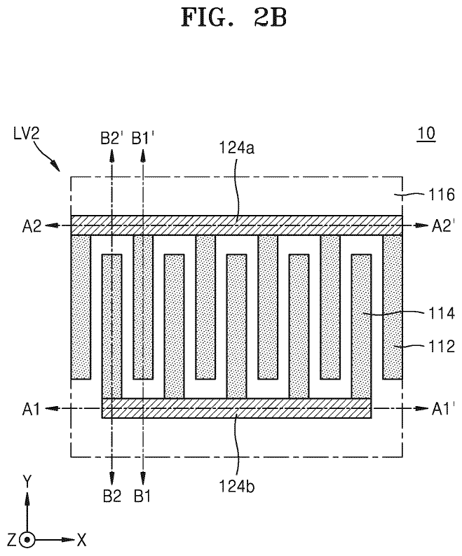

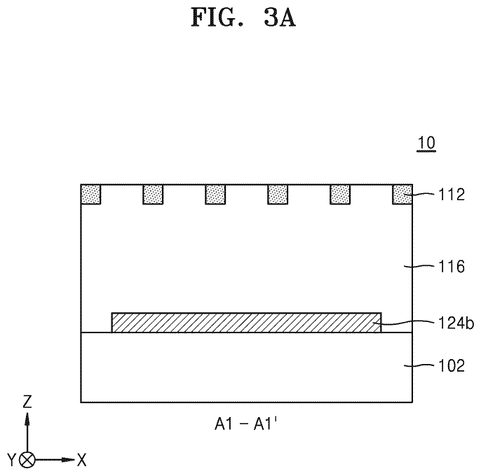

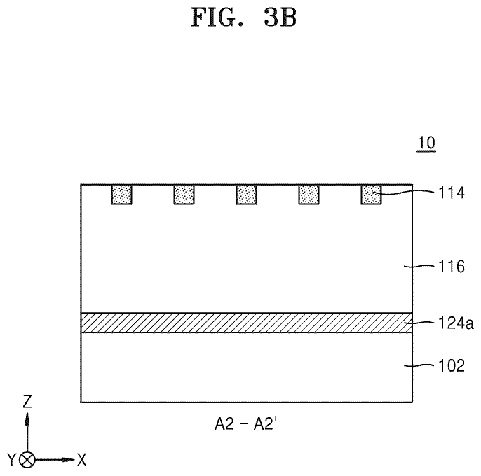

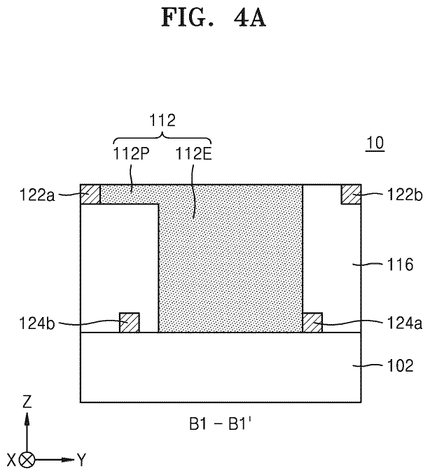

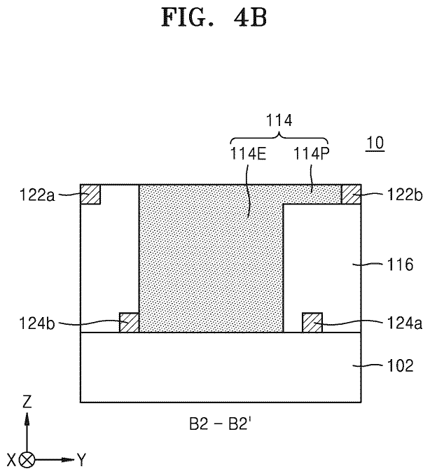

FIG. 1 is a perspective view of an example of a capacitor device according to some implementations. FIG. 2A is a layout diagram of the capacitor structure 10 at an example of a first level LV1 in FIG. 1 according to some implementations. FIG. 2B is a layout diagram of the capacitor structure 10 at an example of a second level LV2 in FIG. 1 according to some implementations. FIG. 3A is a cross-sectional view taken along line A1-A1′ in FIGS. 2A and 2B according to some implementations. FIG. 3B is a cross-sectional view taken along line A2-A2′ in FIGS. 2A and 2B according to some implementations. FIG. 4A is a cross-sectional view taken along line B1-B1′ in FIGS. 2A and 2B according to some implementations. FIG. 4B is a cross-sectional view taken along line B2-B2′ in FIGS. 2A and 2B according to some implementations.

In FIGS. 1, 2A, and 2B, a capacitor device 10 may be provided on a substrate 102. The capacitor device 10 may include a first electrode 112, a second electrode 114, an insulating film 116, an upper wiring layer (e.g., 122a and 122b), and a lower wiring layer (e.g., 124a and 124b). Although it is illustrated that the capacitor structure 10 includes two wiring layers, i.e., the upper wiring layer and the lower wiring layer, implementations are not limited thereto. The capacitor device 10 may include three or more wiring layers.

Herein, the first level LV1 may be higher than the second level LV2. In other words, the distance between the substrate 102 and any element at the first level LV1 may be greater than the distance between the substrate 102 and any element at the second level LV2.

The substrate 102 may include a bulk wafer or a wafer including epitaxial growth. The substrate 102 may include a Group IV semiconductor material, a Group III-V semiconductor material, or a Group II-VI semiconductor material. For example, the Group IV semiconductor material may include silicon (Si), germanium (Ge), or silicon germanium (SiGe). For example, the Group III-V semiconductor material may include gallium arsenide (GaAs), indium phosphide (InP), gallium phosphide (GaP), indium arsenide (InAs), indium antimony (InSb), or indium gallium arsenide (InGaAs). For example, the Group II-VI semiconductor material may include zinc telluride (ZnTe) or cadmium sulfide (CdS). The substrate 102 may include a silicon-on-insulator (SOI) substrate, a quartz substrate, a rigid substrate such as a glass substrate for a display, or a flexible plastic substrate including polyimide, polyethylene terephthalate (PET), polyethylene naphthalate (PEN), poly methyl methacrylate (PMMA), polycarbonate (PC), polyethersulfone (PES), or polyester. The substrate 102 may include a conductive region, e.g., an impurity-doped well or an impurity-doped structure. Other semiconductor devices may be arranged on the substrate 102. For example, the semiconductor devices may include, but not limited to, various device isolation structures such as shallow trench isolation (STI) structures, a transistor, a resistor, or a capacitor.

A lower insulating film (not shown) may be on the substrate 102. The lower insulating film may include silicon oxide or silicon nitride. For example, the lower insulating film may include SiON but is not limited thereto. The lower insulating film may include, but not limited to, at least one selected from the group consisting of hafnium oxide, hafnium silicon oxide, lanthanum oxide, lanthanum aluminum oxide, zirconium oxide, zirconium silicon oxide, tantalum oxide, titanium oxide, aluminum oxide, lead scandium tantalum oxide, and lead zinc niobate. The lower insulating film may include a plurality of films sequentially arranged. Another material film may be between the substrate 102 and the lower insulating film. In some implementations, there may be a conductive plug penetrating through the lower insulating film. The conductive plug may be in contact with the substrate 102.

When the lower insulating film is arranged on the substrate 102, the substrate 102, the lower insulating film, and the first electrode 112 may operate as a capacitor and the substrate 102, the lower insulating film, and the second electrode 114 may operate as a capacitor. The capacitors may include a metal-oxide semiconductor (MOS) capacitor or a varactor.

The lower wiring layer (124a and 124b) may be arranged on the substrate 102. The lower wiring layer (124a and 124b) may be located at the second level LV2 of the capacitor structure 10. The lower wiring layer (124a and 124b) may have a line shape that extends in the first horizontal direction (the X direction). In some implementations, the lower wiring layer (124a and 124b) may include metal, conductive metal nitride, metal silicide, or a combination thereof. For example, the lower wiring layer (124a and 124b) may include a conductive material, such as tungsten, molybdenum, titanium, cobalt, tantalum, nickel, tungsten silicide, titanium silicide, cobalt silicide, tantalum silicide, or nickel silicide.

The insulating film 116 may be arranged on the lower wiring layer (124a and 124b) to cover the surface of the lower wiring layer (124a and 124b). The insulating film 116 may cover the upper surface of the lower wiring layer (124a and 124b) and a sidewall of the lower wiring layer (124a and 124b) that is not covered with the first electrode 112 or the second electrode 114. In some implementations, the insulating film 116 may include at least one selected from the group comprising silicon nitride, a high-k dielectric film having a higher dielectric constant than the silicon nitride, and a ferroelectric material. The high-k dielectric film may include at least one material selected from the group comprising hafnium oxide (HfO), hafnium silicon oxide (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicon oxide (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconium titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO). In some implementations, the insulating film 116 may have a single-layer structure. In some implementations, the insulating film 116 may have a multi-layer structure including at least two layers.

The upper wiring layer (122a and 122b) may be arranged on the insulating film 116. The upper wiring layer (122a and 122b) may be at the first level LV1 of the capacitor structure 10. The upper wiring layer (122a and 122b) may have a line shape that extends in the first horizontal direction (the X direction). In some implementations, similarly to the lower wiring layer (124a and 124b), the upper wiring layer (122a and 122b) may include metal, conductive metal nitride, metal silicide, or a combination thereof. For example, the upper wiring layer (122a and 122b) may include a conductive material, such as tungsten, molybdenum, titanium, cobalt, tantalum, nickel, tungsten silicide, titanium silicide, cobalt silicide, tantalum silicide, or nickel silicide.

The first electrode 112 and the second electrode 114 may be arranged on the substrate 102.

There may be a plurality of first electrodes 112 and a plurality of second electrodes 114. The first electrodes 112 and the second electrodes 114 may extend in the second horizontal direction (the Y direction). The first electrodes 112 and the second electrodes 114 may be spaced apart from each other in the first horizontal direction (the X direction). Each of the second electrodes 114 may be between two adjacent first electrodes 112. In other words, the first electrodes 112 and the second electrodes 114 may be alternately arranged in the first horizontal direction (the X direction).

In some implementations, the first electrodes 112 and the second electrodes 114 may include metal or metal nitride. The metal may include copper, tungsten, aluminum, ruthenium, platinum, titanium, tantalum, etc. The metal nitride may include tungsten nitride, tantalum nitride, titanium nitride, etc.

An end portion of each of the first electrodes 112 may be in contact with a first upper wiring layer 122a. An end portion of each of the second electrodes 114 may be in contact with a second upper wiring layer 122b.

One of the opposite sidewalls of the end portion of each first electrode 112 may be in contact with the first upper wiring layer 122a and the other sidewall of the end portion of the first electrode 112 may be separated from the second upper wiring layer 122b by the insulating film 116. One of the opposite sidewalls of the end portion of each second electrode 114 may be in contact with the second upper wiring layer 122b and the other sidewall of the end portion of the second electrode 114 may be separated from the first upper wiring layer 122a by the insulating film 116. The first electrode 112 may be electrically connected to the first upper wiring layer 122a and the second electrode 114 may be electrically connected to the second upper wiring layer 122b.

The other end portion of the first electrode 112 may be in contact with a first lower wiring layer 124a. The other end portion of the second electrode 114 may be in contact with a second lower wiring layer 124b.

One of the opposite sidewalls of the other end portion of the first electrode 112 may be in contact with the first lower wiring layer 124a and the other sidewall of the other end portion of the first electrode 112 may be separated from the second lower wiring layer 124b by the insulating film 116. One of the opposite sidewalls of the other end portion of the second electrode 114 may be in contact with the second lower wiring layer 124b and the other sidewall of the other end portion of the second electrode 114 may be separated from the first lower wiring layer 124a by the insulating film 116. The first electrode 112 may be electrically connected to the first lower wiring layer 124a and the second electrode 114 may be electrically connected to the second lower wiring layer 124b.

In some implementations, the first electrode 112 and the second electrode 114 facing the first electrode 112 may form a capacitor. In some implementations, the first electrode 112, the second electrode 114 facing the first electrode 112, the first upper wiring layer 122a and the first lower wiring layer 124a that are electrically connected to the first electrode 112, and the second upper wiring layer 122b and the second lower wiring layer 124b that are electrically connected to the second electrode 114 may form a closed loop.

In some implementations, the closed loop may include the first upper wiring layer 122a and the second upper wiring layer 122b at the first level LV1 and the first lower wiring layer 124a and the second lower wiring layer 124b at the second level LV2. In other words, the closed loop may include wiring layers at different vertical levels.

Each of the first electrode 112 and the second electrode 114 may include one sidewall and the other sidewall opposite the one sidewall. In some implementations, the one sidewall of the first electrode 112 may face the first lower wiring layer 124a and the other sidewall of the first electrode 112 may face the first upper wiring layer 122a. The one sidewall of the second electrode 114 may face the second lower wiring layer 124b and the other sidewall of the second electrode 114 may face the second upper wiring layer 122b.

The first upper wiring layer 122a may be spaced apart from the second upper wiring layer 122b in the second horizontal direction (the Y direction). A plurality of first electrodes 112 and a plurality of second electrodes 114 may be between the first upper wiring layer 122a and the second upper wiring layer 122b. The first lower wiring layer 124a may be spaced apart from the second lower wiring layer 124b in the second horizontal direction (the Y direction). The first electrodes 112 and the second electrodes 114 may be between the first lower wiring layer 124a and the second lower wiring layer 124b.

In some implementations, the first electrodes 112 may form a comb shape together with the first upper wiring layer 122a at the first level LV1 and may form a comb shape together with the first lower wiring layer 124a at the second level LV2. For example, the first electrodes 112 may be arranged on a sidewall of the first upper wiring layer 122a and a sidewall of the first lower wiring layer 124a and spaced apart from each other. The second electrodes 114 may form a comb shape together with the second upper wiring layer 122b at the first level LV1 and may form a comb shape together with the second lower wiring layer 124b at the second level LV2. For example, the second electrodes 114 may be arranged on a sidewall of the second upper wiring layer 122b and a sidewall of the second lower wiring layer 124b and spaced apart from each other.

In some implementations, each of the first electrodes 112 and the second electrodes 114 may have a plate shape that extends in the vertical direction (the Z direction). Each of the first electrodes 112 may include a first base portion 112E, which is between the first lower wiring layer 124a and the second lower wiring layer 124b and extends in the vertical direction (the Z direction), and a first pad portion 112P, which extends from the first base portion 112E in the second horizontal direction (the Y direction) and is in contact with the first upper wiring layer 122a. The first pad portion 112P may be between the first upper wiring layer 122a and the second upper wiring layer 122b. The first pad portion 112P may protrude from the first base portion 112E toward the first upper wiring layer 122a. Similar to the first electrodes 112, each of the second electrodes 114 may include a second base portion 114E, which is between the first lower wiring layer 124a and the second lower wiring layer 124b and extends in the vertical direction (the Z direction), and a second pad portion 114P, which extends from the second base portion 114E in the second horizontal direction (the Y direction) and is in contact with the second upper wiring layer 122b. The second pad portion 114P may be between the first upper wiring layer 122a and the second upper wiring layer 122b. The second pad portion 114P may protrude from the second base portion 114E toward the second upper wiring layer 122b.

In some implementations, the first lower wiring layer 124a may be in contact with the first base portion 112E, the first upper wiring layer 122a may be in contact with the first pad portion 112P, the second lower wiring layer 124b may be in contact with the second base portion 114E, and the second upper wiring layer 122b may be in contact with the second pad portion 114P.

The first lower wiring layer 124a, the first upper wiring layer 122a, and the second upper wiring layer 122b may not overlap the first electrodes 112 in the vertical direction (the Z direction), but the second lower wiring layer 124b may overlap at least a part of the first pad portion 112P of each first electrode 112 in the vertical direction (the Z direction). The first pad portion 112P of the first electrode 112 may be separated from the second lower wiring layer 124b by the insulating film 116 in the vertical direction (the Z direction). The second lower wiring layer 124b, the first upper wiring layer 122a, and the second upper wiring layer 122b may not overlap the second electrodes 114 in the vertical direction (the Z direction), but the first lower wiring layer 124a may overlap at least a part of the second pad portion 114P of each second electrode 114 in the vertical direction (the Z direction). The second pad portion 114P of the second electrode 114 may be separated from the first lower wiring layer 124a by the insulating film 116 in the vertical direction (the Z direction).

However, each of the first electrode 112 and the second electrode 114 is not limited to a plate shape extending in the vertical direction (the Z direction) and may have various shapes. In some implementations, each of the first electrode 112 and the second electrode 114 may include a plurality of conductive lines (not shown), which are spaced apart from each other in the vertical direction (the Z direction). At least one conductive contact may be between the conductive lines and may thus electrically connect the conductive lines. For example, the first electrode 112 may include a first conductive line connected to the first upper wiring layer 122a, a second conductive line connected to the first lower wiring layer 124a, and at least one conductive contact electrically connecting the first conductive line to the second conductive line.

A first voltage may be applied to the first electrode 112 and a second voltage may be applied to the second electrode 114. The first electrode 112, the second electrode 114 facing a sidewall of the first electrode 112, and a portion of the insulating film 116 between the first electrode 112 and the second electrode 114 may operate as a first capacitor. The first capacitor may include a vertical natural capacitor (VNCAP).

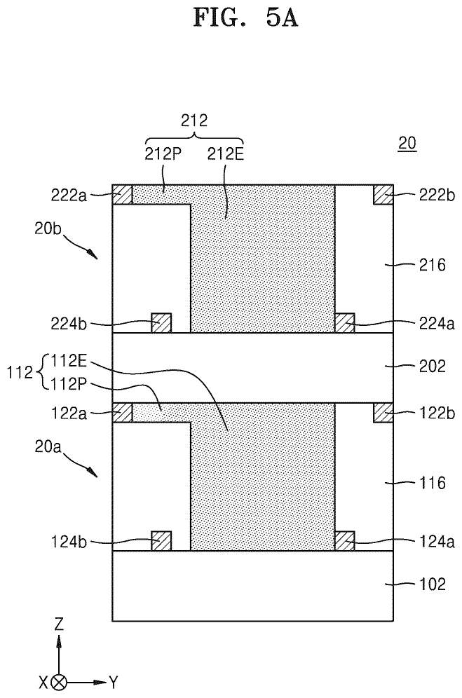

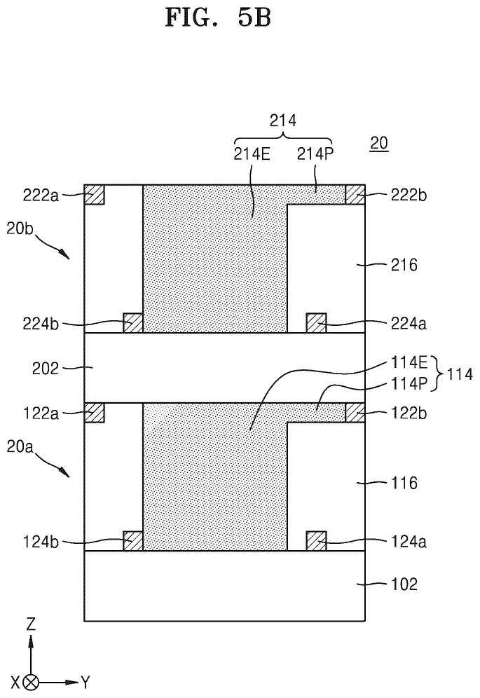

FIG. 5A is a diagram illustrating an example of a capacitor device according to some implementations. FIG. 5B is a diagram illustrating an example of a capacitor device according to some implementations. FIG. 5A may correspond to a cross-sectional view taken along line B1-B1′ in FIGS. 2A and 2B, and FIG. 5B may correspond to a cross-sectional view taken along line B2-B2′ in FIGS. 2A and 2B.

In FIGS. 5A and 5B, a capacitor device 20 may be configured substantially similar to the capacitor device 10, and the capacitor device 20 is described focusing on the differences from the capacitor device 10. In FIGS. 1 to 5B, like reference characters or numerals denote like elements, and redundant descriptions thereof will be omitted.

In FIGS. 5A and 5B, the capacitor device 20 may include a lower structure 20a and an upper structure 20b. Each of the lower structure 20a and the upper structure 20b may be configured identically or similarly to the capacitor device 10 described with reference to FIGS. 1 to 4B.

The lower structure 20a may be arranged on the substrate 102 and may include a first electrode 112, a second electrode 114, an insulating film 116, an upper wiring layer (e.g., 122a and 122b), and a lower wiring layer (e.g., 124a and 124b). The first electrode 112, the second electrode 114, the insulating film 116, the upper wiring layer (122a and 122b), and the lower wiring layer (124a and 124b) may be respectively similar to the first electrode 112, the second electrode 114, the insulating film 116, the upper wiring layer (122a and 122b), and the lower wiring layer (124a and 124b) of the capacitor device 10.

The upper structure 20b may be arranged on an interlayer insulating film 202. The upper structure 20b may be separated from the lower structure 20a by the interlayer insulating film 202. The upper structure 20b may include a third electrode 212, a fourth electrode 214, an insulating film 216, an upper interlayer wiring layer (e.g., 222a and 222b), and a lower interlayer wiring layer (e.g., 224a and 224b).

The interlayer insulating film 202 may cover the upper surface of the lower structure 20a. The interlayer insulating film 202 may include silicon oxide or silicon nitride. For example, the interlayer insulating film 202 may include SiON but is not limited thereto. As another example, the interlayer insulating film 202 may include, but not limited to, at least one selected from the group consisting of hafnium oxide, hafnium silicon oxide, lanthanum oxide, lanthanum aluminum oxide, zirconium oxide, zirconium silicon oxide, tantalum oxide, titanium oxide, aluminum oxide, lead scandium tantalum oxide, and lead zinc niobate. The interlayer insulating film 202 may include a plurality of films sequentially arranged. Another material film may be between the interlayer insulating film 202 and the lower structure 20a. There may be a conductive plug penetrating through the interlayer insulating film 202. The conductive plug may penetrate through the interlayer insulating film 202 and be in contact with the substrate 102, the first electrode 112, or the second electrode 114.

The lower interlayer wiring layer (224a and 224b) may be arranged on the interlayer insulating film 202, and the insulating film 216 may cover the surface of the lower interlayer wiring layer (224a and 224b). The lower interlayer wiring layer (224a and 224b) may be at the second level LV2 of the capacitor structure 20. The lower interlayer wiring layer (224a and 224b) may include metal, conductive metal nitride, metal silicide, or a combination thereof. For example, the lower interlayer wiring layer (224a and 224b) may include a conductive material, such as tungsten, molybdenum, titanium, cobalt, tantalum, nickel, tungsten silicide, titanium silicide, cobalt silicide, tantalum silicide, or nickel silicide.

The insulating film 216 may include a similar material to the insulating film 116 described with reference to FIGS. 1 to 4B. In some implementations, the insulating film 216 may have a single-layer structure. In some implementations, the insulating film 216 may have a multi-layer structure including at least two layers.

The upper interlayer wiring layer (222a and 222b) may be arranged on the insulating film 216. The upper interlayer wiring layer (222a and 222b) may be at a higher vertical level than the lower interlayer wiring layer (224a and 224b). The upper interlayer wiring layer (222a and 222b) may include a similar material to the lower interlayer wiring layer (224a and 224b).

The third electrode 212 and the fourth electrode 214 may be arranged on the interlayer insulating film 202. There may be a plurality of third electrodes 212 and a plurality of fourth electrodes 214. The third electrodes 212 may be spaced apart from each other in the first horizontal direction (the X direction), and a fourth electrode 214 may be between adjacent third electrodes 212. In other words, the third electrodes 212 and the fourth electrodes 214 may be alternately arranged in the first horizontal direction (the X direction).

In some implementations, the third electrodes 212 and the fourth electrodes 214 may include metal or metal nitride. The metal may include copper, tungsten, aluminum, ruthenium, platinum, titanium, tantalum, etc. The metal nitride may include tungsten nitride, tantalum nitride, titanium nitride, etc.

The connection relationship between each of the third electrodes 212 and the fourth electrodes 214 and the upper interlayer wiring layer (222a and 222b) may be substantially the same as the connection relationship between each of the first electrodes 112 and the second electrodes 114 and the upper wiring layer (122a and 122b). The connection relationship between each of the third electrodes 212 and the fourth electrodes 214 and the lower interlayer wiring layer (224a and 224b) may be substantially the same as the connection relationship between each of the first electrodes 112 and the second electrodes 114 and the lower wiring layer (124a and 124b).

An end portion of each of the third electrodes 212 may be in contact with the upper interlayer wiring layer (e.g., 222a). The upper interlayer wiring layer that is in contact with the end portion of each third electrode 212 may be referred to as a first upper interlayer wiring layer 222a. An end portion of each of the fourth electrodes 214 may be in contact with the upper interlayer wiring layer (e.g., 222b). The upper interlayer wiring layer that is in contact with the end portion of each fourth electrode 214 may be referred to as a second upper interlayer wiring layer 222b.

One of the opposite sidewalls of the end portion of the third electrode 212 may be in contact with the first upper interlayer wiring layer 222a, and the other sidewall of the end portion of the third electrode 212 may be separated from the second upper interlayer wiring layer 222b by the insulating film 216. One of the opposite sidewalls of the end portion of the fourth electrode 214 may be in contact with the second upper interlayer wiring layer 222b, and the other sidewall of the end portion of the fourth electrode 214 may be separated from the first upper interlayer wiring layer 222a by the insulating film 216. The third electrode 212 may be electrically connected to the first upper interlayer wiring layer 222a and the fourth electrode 214 may be electrically connected to the second upper interlayer wiring layer 222b.

The other end portion of the third electrode 212 may be in contact with the lower interlayer wiring layer (e.g., 224a). The lower interlayer wiring layer that is in contact with the other end portion of the third electrode 212 may be referred to as a first lower interlayer wiring layer 224a. The other end portion of the fourth electrode 214 may be in contact with the lower interlayer wiring layer (e.g., 224b). The lower interlayer wiring layer that is in contact with the other end portion of the fourth electrode 214 may be referred to as a second lower interlayer wiring layer 224b.

One of the opposite sidewalls of the other end portion of the third electrode 212 may be in contact with the first lower interlayer wiring layer 224a, and the other sidewall of the other end portion of the third electrode 212 may be separated from the second lower interlayer wiring layer 224b by the insulating film 216. One of the opposite sidewalls of the other end portion of the fourth electrode 214 may be in contact with the second lower interlayer wiring layer 224b, and the other sidewall of the other end portion of the fourth electrode 214 may be separated from the first lower interlayer wiring layer 224a by the insulating film 216. The third electrode 212 may be electrically connected to the first lower interlayer wiring layer 224a and the fourth electrode 214 may be electrically connected to the second lower interlayer wiring layer 224b.

In some implementations, the third electrode 212 and the fourth electrode 214 facing the third electrode 212 may form a capacitor. In some implementations, the third electrode 212, the fourth electrode 214 facing the third electrode 212, the first upper interlayer wiring layer 222a and the first lower interlayer wiring layer 224a that are electrically connected to the third electrode 212, and the second upper interlayer wiring layer 222b and the second lower interlayer wiring layer 224b that are electrically connected to the fourth electrode 214 may form a closed loop.

In some implementations, the closed loop may include the first upper interlayer wiring layer 222a and the second upper interlayer wiring layer 222b, which are at an arbitrary vertical level, and the first lower interlayer wiring layer 224a and the second lower interlayer wiring layer 224b, which are at a vertical level lower than the arbitrary vertical level. In other words, the closed loop may include wiring layers at different vertical levels.

Each of the third electrode 212 and the fourth electrode 214 may include one sidewall and the other sidewall opposite the one sidewall. In some implementations, the first lower interlayer wiring layer 224a may face one of the opposite sidewalls of the third electrode 212 and the first upper interlayer wiring layer 222a may face the other sidewall of the third electrode 212. The second lower interlayer wiring layer 224b may face one of the opposite sidewalls of the fourth electrode 214 and the second upper interlayer wiring layer 222b may face the other sidewall of the fourth electrode 214.

The first upper interlayer wiring layer 222a may be spaced apart from the second upper interlayer wiring layer 222b in the second horizontal direction (the Y direction). A plurality of third electrodes 212 and a plurality of fourth electrodes 214 may be between the first upper interlayer wiring layer 222a and the second upper interlayer wiring layer 222b. The first lower interlayer wiring layer 224a may be spaced apart from the second lower interlayer wiring layer 224b in the second horizontal direction (the Y direction). The third electrodes 212 and the fourth electrodes 214 may be between the first lower interlayer wiring layer 224a and the second lower interlayer wiring layer 224b.

In some implementations, the third electrodes 212 may form a comb shape together with the first upper interlayer wiring layer 222a and the first lower interlayer wiring layer 224a and the fourth electrodes 214 may form a comb shape together with the second upper interlayer wiring layer 222b and the second lower interlayer wiring layer 224b. For example, the third electrodes 212 may be arranged on a sidewall of the first upper interlayer wiring layer 222a to be spaced apart from each other and may be arranged on a sidewall of the first lower interlayer wiring layer 224a to be spaced apart from each other. The fourth electrodes 214 may be arranged on a sidewall of the second upper interlayer wiring layer 222b to be spaced apart from each other and may be arranged on a sidewall of the second lower interlayer wiring layer 224b to be spaced apart from each other.

In some implementations, the capacitor device 20 may include a plurality of electrodes at different vertical levels in addition to the first electrodes 112, the third electrodes 212, the second electrodes 114, and the fourth electrodes 214. For example, a plurality of electrodes at different vertical levels may include a first electrode group in a first layer, a second electrode group in a second layer that is at a different vertical level than the first electrode group, and an N-th electrode group (N is a natural number of at least 1). The capacitor device 20 may include a plurality of wiring layers at different vertical levels in addition to the upper wiring layer (122a and 122b), the lower wiring layer 124a and 124b), the upper interlayer wiring layer (222a and 222b), and the lower interlayer wiring layer (224a and 224b). For example, a plurality of wiring layers at different vertical levels may include a first wiring layer group in a first layer, a second wiring layer group in a second layer that is at a different vertical level than the first wiring layer group, and an M-th wiring layer group (M is a natural number of at least 1). In some embodiments, N may be less than M.

In some implementations, each of the third electrodes 212 and the fourth electrodes 214 may have a plate shape that extends in the vertical direction (the Z direction). Each of the third electrodes 212 may include a third base portion 212E, which is between the first lower interlayer wiring layer 224a and the second lower interlayer wiring layer 224b and extends in the vertical direction (the Z direction), and a third pad portion 212P, which extends from the third base portion 212E in the second horizontal direction (the Y direction) and is in contact with the first upper interlayer wiring layer 222a. The third pad portion 212P may be between the first upper interlayer wiring layer 222a and the second upper interlayer wiring layer 222b. Similar to the third electrodes 212, each of the fourth electrodes 214 may include a fourth base portion 214E, which is between the first lower interlayer wiring layer 224a and the second lower interlayer wiring layer 224b and extends in the vertical direction (the Z direction), and a fourth pad portion 214P, which extends from the fourth base portion 214E in the second horizontal direction (the Y direction) and is in contact with the second upper interlayer wiring layer 222b. The fourth pad portion 214P may be between the first upper interlayer wiring layer 222a and the second upper interlayer wiring layer 222b.

The first lower interlayer wiring layer 224a, the first upper interlayer wiring layer 222a, and the second upper interlayer wiring layer 222b may not overlap each of the third electrodes 212 in the vertical direction (the Z direction), but the second lower interlayer wiring layer 224b may overlap the third pad portion 212P of each third electrode 212 in the vertical direction (the Z direction). The third pad portion 212P of the third electrode 212 may be separated from the second lower interlayer wiring layer 224b by the insulating film 216 in the vertical direction (the Z direction). The second lower interlayer wiring layer 224b, the first upper interlayer wiring layer 222a, and the second upper interlayer wiring layer 222b may not overlap each of the fourth electrodes 214 in the vertical direction (the Z direction), but the first lower interlayer wiring layer 224a may overlap the fourth pad portion 214P of each fourth electrode 214 in the vertical direction (the Z direction). The fourth pad portion 214P of the fourth electrode 214 may be separated from the first lower interlayer wiring layer 224a by the insulating film 216 in the vertical direction (the Z direction).

In some implementations, the first pad portion 112P of each of the first electrodes 112 may overlap at least a part of the third pad portion 212P of the third electrode 212 in the vertical direction (the Z direction). For example, a sidewall of the first base portion 112E of the first electrode 112, which the first pad portion 112P of the first electrode 112 faces, may be coplanar with a sidewall of the third base portion 212E of the third electrode 212, which the third pad portion 212P of the third electrode 212 faces. In some implementations, the second pad portion 114P of each of the second electrodes 114 may overlap at least a part of the fourth pad portion 214P of the fourth electrode 214 in the vertical direction (the Z direction). For example, a sidewall of the second base portion 114E of the second electrode 114, which the second pad portion 114P of the second electrode 114 faces, may be coplanar with a sidewall of the fourth base portion 214E of the fourth electrode 214, which the fourth pad portion 214P of the fourth electrode 214 faces.

However, each of the third electrode 212 and the fourth electrode 214 is not limited to a plate shape extending in the vertical direction (the Z direction) and may have various shapes. In some implementations, each of the third electrode 212 and the fourth electrode 214 may include a plurality of conductive lines (not shown), which are spaced apart from each other in the vertical direction (the Z direction). At least one conductive contact may be between the conductive lines and may electrically interconnect the conductive lines. For example, the third electrode 212 may include a first conductive line connected to the first upper interlayer wiring layer 222a, a second conductive line connected to the first lower interlayer wiring layer 224a, and at least one conductive contact electrically connecting the first conductive line to the second conductive line.

The first electrode 112, the second electrode 114 facing a sidewall of the first electrode 112, and a portion of the insulating film 116 between the first electrode 112 and the second electrode 114 may operate as a first capacitor. The third electrode 212, the fourth electrode 214 facing a sidewall of the third electrode 212, and a portion of the insulating film 216 between the third electrode 212 and the fourth electrode 214 may operate as a second capacitor. The second capacitor may include a VNCAP. The first electrode 112, the third electrode 212, and a portion of the interlayer insulating film 202 between the first electrode 112 and the third electrode 212 may operate as a third capacitor. The second electrode 114, the fourth electrode 214, and a portion of the interlayer insulating film 202 between the second electrode 114 and the fourth electrode 214 may operate as a fourth capacitor.

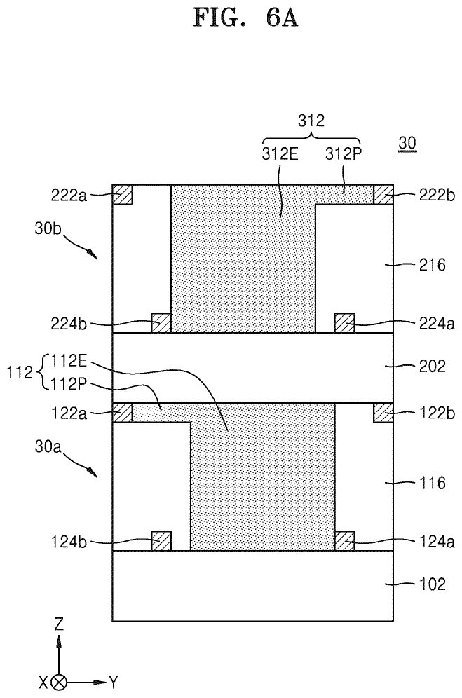

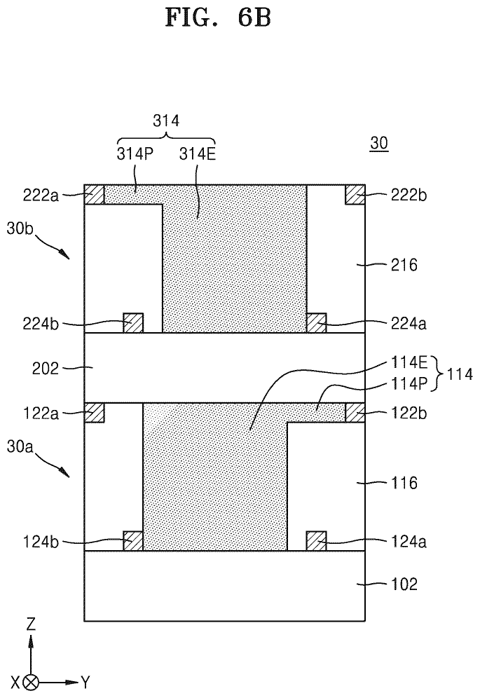

FIG. 6A is a diagram illustrating an example of a capacitor device according to some implementations. FIG. 6B is a diagram illustrating an example of a capacitor device according to some implementations. FIG. 6A may correspond to a cross-sectional view taken along line B1-B1′ in FIGS. 2A and 2B. FIG. 6B may correspond to a cross-sectional view taken along line B2-B2′in FIGS. 2A and 2B.

In FIGS. 6A and 6B, a capacitor device 30 is configured substantially similar to the capacitor device 20, and the capacitor device 30 is described focusing on the differences from the capacitor device 20. In FIGS. 1 to 6B, like reference characters or numerals denote like elements, and redundant descriptions thereof will be omitted.

In FIGS. 6A and 6B, the capacitor device 30 may include a lower structure 30a and an upper structure 30b. Each of the lower structure 30a and the upper structure 30b may be configured identically or similarly to the capacitor device 10 described with reference to FIGS. 1 to 4B.

The lower structure 30a may be arranged on the substrate 102 and may include a first electrode 112, a second electrode 114, an insulating film 116, an upper wiring layer (e.g., 122a and 122b), and a lower wiring layer (e.g., 124a and 124b). The first electrode 112, the second electrode 114, the insulating film 116, the upper wiring layer (122a and 122b), and the lower wiring layer (124a and 124b) may be respectively similar to the first electrode 112, the second electrode 114, the insulating film 116, the upper wiring layer (122a and 122b), and the lower wiring layer (124a and 124b) of the capacitor device 10.

The lower wiring layer (124a and 124b) of the lower structure 30a may be at the second level LV2 and the upper wiring layer (122a and 122b) of the lower structure 30a may be at the first level LV1. The upper structure 30b may be arranged on the interlayer insulating film 202. The upper structure 30b may be separated from the lower structure 30a by the interlayer insulating film 202. The upper structure 30b may include a third electrode 312, a fourth electrode 314, the insulating film 216, an upper interlayer wiring layer (e.g., 222a and 222b), and a lower interlayer wiring layer (e.g., 224a and 224b).

The third electrode 312 and the fourth electrode 314 may be arranged on the interlayer insulating film 202. There may be a plurality of third electrodes 312 and a plurality of fourth electrodes 314. Each of the third electrodes 312 and the fourth electrodes 314 may extend in the second horizontal direction (the Y direction). The third electrodes 312 and the fourth electrodes 314 may be spaced apart from each other in the first horizontal direction (the X direction), and a fourth electrode 314 may be between adjacent third electrodes 312. In other words, the third electrodes 312 and the fourth electrodes 314 may be alternately arranged in the first horizontal direction (the X direction).

In some implementations, the third electrodes 312 and the fourth electrodes 314 may include metal or metal nitride. The metal may include copper, tungsten, aluminum, ruthenium, platinum, titanium, tantalum, etc. The metal nitride may include tungsten nitride, tantalum nitride, titanium nitride, etc.

An end portion of each of the third electrodes 312 may be in contact with the upper interlayer wiring layer (e.g., 222b). The upper interlayer wiring layer that is in contact with the end portion of each third electrode 312 may be referred to as a first upper interlayer wiring layer 222b. An end portion of each of the fourth electrodes 314 may be in contact with the upper interlayer wiring layer (e.g., 222a). The upper interlayer wiring layer that is in contact with the end portion of each fourth electrode 314 may be referred to as a second upper interlayer wiring layer 222a.

One of the opposite sidewalls of the end portion of the third electrode 312 may be in contact with the first upper interlayer wiring layer 222b, and the other sidewall of the end portion of the third electrode 312 may be separated from the second upper interlayer wiring layer 222a by the insulating film 216. One of the opposite sidewalls of the end portion of the fourth electrode 314 may be in contact with the second upper interlayer wiring layer 222a, and the other sidewall of the end portion of the fourth electrode 314 may be separated from the first upper interlayer wiring layer 222b by the insulating film 216. The third electrode 312 may be electrically connected to the first upper interlayer wiring layer 222b and the fourth electrode 314 may be electrically connected to the second upper interlayer wiring layer 222a.

The other end portion of the third electrode 312 may be in contact with the lower interlayer wiring layer (e.g., 224b). The lower interlayer wiring layer that is in contact with the other end portion of the third electrode 312 may be referred to as a first lower interlayer wiring layer 224b. The other end portion of the fourth electrode 314 may be in contact with the lower interlayer wiring layer (e.g., 224a). The lower interlayer wiring layer that is in contact with the other end portion of the fourth electrode 314 may be referred to as a second lower interlayer wiring layer 224a.

One of the opposite sidewalls of the other end portion of the third electrode 312 may be in contact with the first lower interlayer wiring layer 224b, and the other sidewall of the other end portion of the third electrode 312 may be separated from the second lower interlayer wiring layer 224a by the insulating film 216. One of the opposite sidewalls of the other end portion of the fourth electrode 314 may be in contact with the second lower interlayer wiring layer 224a, and the other sidewall of the other end portion of the fourth electrode 314 may be separated from the first lower interlayer wiring layer 224b by the insulating film 216. The third electrode 312 may be electrically connected to the first lower interlayer wiring layer 224b and the fourth electrode 314 may be electrically connected to the second lower interlayer wiring layer 224a.

In some implementations, a first of the opposite sidewalls of each of the third electrode 312 and the fourth electrode 314 may face the second upper interlayer wiring layer 222a and the first lower interlayer wiring layer 224b and a second sidewall of each of the third electrode 312 and the fourth electrode 314 may face the first upper interlayer wiring layer 222b and the second lower interlayer wiring layer 224a.

The first upper interlayer wiring layer 222b may be spaced apart from the second upper interlayer wiring layer 222a in the second horizontal direction (the Y direction). A plurality of third electrodes 312 and a plurality of fourth electrodes 314 may be between the first upper interlayer wiring layer 222b and the second upper interlayer wiring layer 222a. The first lower interlayer wiring layer 224b may be spaced apart from the second lower interlayer wiring layer 224a in the second horizontal direction (the Y direction). The third electrodes 312 and the fourth electrodes 314 may be between the first lower interlayer wiring layer 224b and the second lower interlayer wiring layer 224a.

In some implementations, the third electrodes 312 may form a comb shape together with the first upper interlayer wiring layer 222b and the first lower interlayer wiring layer 224b and the fourth electrodes 314 may form a comb shape together with the second upper interlayer wiring layer 222a and the second lower interlayer wiring layer 224a. For example, the third electrodes 312 may be arranged on a sidewall of the first upper interlayer wiring layer 222b to be spaced apart from each other and may be arranged on a sidewall of the first lower interlayer wiring layer 224b to be spaced apart from each other. The fourth electrodes 314 may be arranged on a sidewall of the second upper interlayer wiring layer 222a to be spaced apart from each other and may be arranged on a sidewall of the second lower interlayer wiring layer 224a to be spaced apart from each other.

In some implementations, each of the third electrodes 312 and the fourth electrodes 314 may have a plate shape that extends in the vertical direction (the Z direction). However, each of the third electrodes 312 and the fourth electrodes 314 is not limited to a plate shape extending in the vertical direction (the Z direction) and may have various shapes, such as a line shape. Each of the third electrodes 312 may include a third base portion 312E, which is between the first lower interlayer wiring layer 224b and the second lower interlayer wiring layer 224a and extends in the vertical direction (the Z direction), and a third pad portion 312P, which extends from the third base portion 312E in the second horizontal direction (the Y direction) and is in contact with the first upper interlayer wiring layer 222b. The third pad portion 312P may be between the first upper interlayer wiring layer 222b and the second upper interlayer wiring layer 222a. Similar to the third electrodes 312, each of the fourth electrodes 314 may include a fourth base portion 314E, which is between the first lower interlayer wiring layer 224b and the second lower interlayer wiring layer 224a and extends in the vertical direction (the Z direction), and a fourth pad portion 314P, which extends from the fourth base portion 314E in the second horizontal direction (the Y direction) and is in contact with the second upper interlayer wiring layer 222a. The fourth pad portion 314P may be between the first upper interlayer wiring layer 222b and the second upper interlayer wiring layer 222a.

The first lower interlayer wiring layer 224b, the first upper interlayer wiring layer 222b, and the second upper interlayer wiring layer 222a may not overlap each of the third electrodes 312 in the vertical direction (the Z direction), but the second lower interlayer wiring layer 224a may overlap the third pad portion 312P of each third electrode 312 in the vertical direction (the Z direction). The third pad portion 312P of the third electrode 312 may be separated from the second lower interlayer wiring layer 224a by the insulating film 216 in the vertical direction (the Z direction). The second lower interlayer wiring layer 224a, the first upper interlayer wiring layer 222b, and the second upper interlayer wiring layer 222a may not overlap each of the fourth electrodes 314 in the vertical direction (the Z direction), but the first lower interlayer wiring layer 224b may overlap the fourth pad portion 314P of each fourth electrode 314 in the vertical direction (the Z direction). The fourth pad portion 314P of the fourth electrode 314 may be separated from the first lower interlayer wiring layer 224b by the insulating film 216 in the vertical direction (the Z direction).

In some implementations, the first pad portion 112P of each of the first electrodes 112 may not overlap the third pad portion 312P of the third electrode 312 in the vertical direction (the Z direction). For example, a sidewall of the first base portion 112E of the first electrode 112, which the first pad portion 112P of the first electrode 112 faces, may be on a different plane than a sidewall of the third base portion 312E of the third electrode 312, which the third pad portion 312P of the third electrode 312 faces. In some embodiments, the second pad portion 114P of each of the second electrodes 114 may not overlap the fourth pad portion 314P of the fourth electrode 314 in the vertical direction (the Z direction). For example, a sidewall of the second base portion 114E of the second electrode 114, which the second pad portion 114P of the second electrode 114 faces, may be on a different plane than a sidewall of the fourth base portion 314E of the fourth electrode 314, which the fourth pad portion 314P of the fourth electrode 314 faces.

The first electrode 112, the second electrode 114 facing a sidewall of the first electrode 112, and a portion of the insulating film 116 between the first electrode 112 and the second electrode 114 may operate as a first capacitor. The third electrode 312, the fourth electrode 314 facing a sidewall of the third electrode 312, and a portion of the insulating film 216 between the third electrode 312 and the fourth electrode 314 may operate as a second capacitor. The second capacitor may include a VNCAP. The first electrode 112, the third electrode 312, and a portion of the interlayer insulating film 202 between the first electrode 112 and the third electrode 312 may operate as a third capacitor. The second electrode 114, the fourth electrode 314, and a portion of the interlayer insulating film 202 between the second electrode 114 and the fourth electrode 314 may operate as a fourth capacitor.

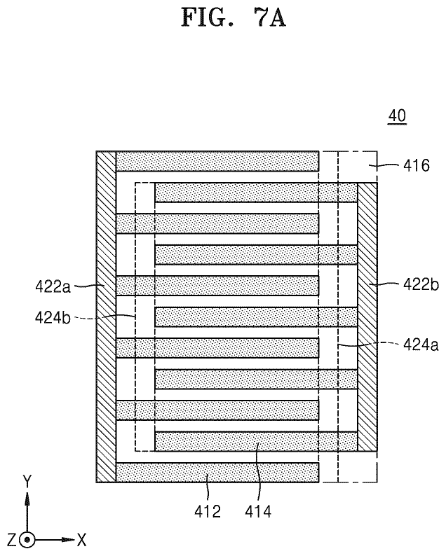

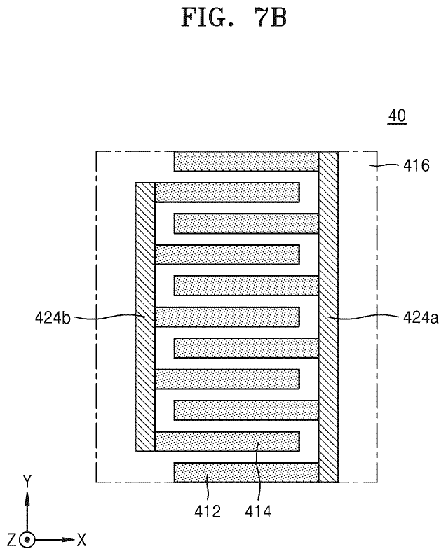

FIG. 7A is a diagram illustrating an example of a capacitor device according to some implementations. FIG. 7B is a diagram illustrating an example of a capacitor device according to some implementations. FIG. 7A may correspond to the layout of the capacitor device 40 at the first level LV1 in FIG. 1, and FIG. 7B may correspond to the layout of the capacitor device 40 at the second level LV2 in FIG. 1.

In FIGS. 7A and 7B, a capacitor device 40 is configured substantially similar to the capacitor device 10, and the capacitor device 40 is described focusing on the differences from the capacitor device 10. In FIGS. 1 to 4B and FIGS. 7A and 7B, like reference characters or numerals denote like elements, and redundant descriptions thereof will be omitted.

In FIGS. 7A and 7B, the capacitor device 40 may be provided on a substrate (not shown). The capacitor device 40 may include a first electrode 412, a second electrode 414, an insulating film 416, an upper wiring layer (e.g., 422a and 422b), and a lower wiring layer (e.g., 424a and 424b). Although it is illustrated that the capacitor device 40 includes two wiring layers, i.e., the upper wiring layer (422a and 422b) and the lower wiring layer (424a and 424b), implementations are not limited thereto. The capacitor device 40 may include three or more wiring layers.

The lower wiring layer (424a and 424b) may be arranged on the substrate. The lower wiring layer (424a and 424b) may be at the second level LV2 of the capacitor device 40. The lower wiring layer (424a and 424b) may have a line shape that extends in the second horizontal direction (the Y direction). In some implementations, the lower wiring layer (424a and 424b) may include metal, conductive metal nitride, metal silicide, or a combination thereof.

The insulating film 416 may be arranged on the lower wiring layer (424a and 424b) and cover the surface of the lower wiring layer (424a and 424b). The insulating film 416 may include a similar material to the insulating film 116 of the capacitor device 10 described with reference to FIGS. 1 to 4B. In some implementations, the insulating film 416 may have a single-layer structure. In some implementations, the insulating film 416 may have a multi-layer structure including at least two layers.

The upper wiring layer (422a and 422b) may be arranged on the insulating film 416. The upper wiring layer (422a and 422b) may be at the first level LV1 of the capacitor device 40. The upper wiring layer (422a and 422b) may have a line shape that extends in the second horizontal direction (the Y direction). In some implementations, similar to the lower wiring layer (424a and 424b), the upper wiring layer (422a and 422b) may include metal, conductive metal nitride, metal silicide, or a combination thereof.

The first electrode 412 and the second electrode 414 may be arranged on the substrate. A plurality of first electrodes 412 and a plurality of second electrodes 414 may extend in the first horizontal direction (the X direction) and may be spaced apart from each other in the second horizontal direction (the Y direction). Each of the second electrodes 414 may be between two adjacent first electrodes 412. In other words, the first electrodes 412 and the second electrodes 414 may be alternately arranged in the second horizontal direction (the Y direction).

The connection relationship between each of the first electrodes 412 and the second electrodes 414 and the upper wiring layer (422a and 422b) may be substantially the same as the connection relationship between each of the first electrodes 112 and the second electrodes 114 and the upper wiring layer (122a and 122b) described above with reference to FIGS. 1 to 4B. The connection relationship between each of the first electrodes 412 and the second electrodes 414 and the lower interlayer wiring layer (424a and 424b) may be substantially the same as the connection relationship between each of the first electrodes 112 and the second electrodes 114 and the lower wiring layer (124a and 124b) described above with reference to FIGS. 1 to 4B.

In some implementations, the first electrodes 412 may form a comb shape together with a first upper wiring layer 422a at the first level LV1 (in FIG. 1) and may form a comb shape together with the first lower wiring layer 424a at the second level LV2 (in FIG. 1). For example, the first electrodes 412 may be arranged on a sidewall of the first upper wiring layer 422a and a sidewall of the first lower wiring layer 424a and spaced apart from each other. The second electrodes 414 may form a comb shape together with the second upper wiring layer 422b at the first level LV1 (in FIG. 1) and may form a comb shape together with the second lower wiring layer 424b at the second level LV2 (in FIG. 1). For example, the second electrodes 414 may be arranged on a sidewall of the second upper wiring layer 422b and a sidewall of the second lower wiring layer 424b to be spaced apart from each other.

Similar to the first electrode 112 and the second electrode 114 described above with reference to FIGS. 1 to 4B, each of the first electrodes 412 may include a first base portion, which is between the first lower wiring layer 424a and the second lower wiring layer 424b and extends in the vertical direction (the Z direction), and a first pad portion, which extends from the first base portion in the first horizontal direction (the X direction) and is in contact with the first upper wiring layer 422a. Each of the second electrodes 414 may include a second base portion (not shown), which is between the first lower wiring layer 424a and the second lower wiring layer 424b and extends in the vertical direction (the Z direction), and a second pad portion, which extends from the second base portion in the first horizontal direction (the X direction) and is in contact with the second upper wiring layer 422b.

A first voltage may be applied to each first electrode 412 and a second voltage may be applied to each second electrode 414 The first electrode 412, the second electrode 414 facing a sidewall of the first electrode 412, and a portion of the insulating film 416 between the first electrode 412 and the second electrode 414 may operate as a first capacitor.

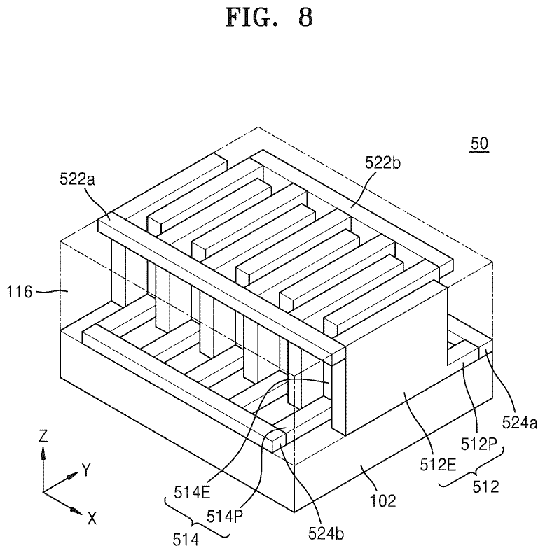

FIG. 8 is a diagram illustrating an example of a capacitor device according to some implementations. In FIG. 8, a capacitor device 50 is configured substantially similar to the capacitor device 10, and thus, the capacitor device 50 is described focusing on the differences from the capacitor device 10. In FIGS. 1 to 4B and FIG. 8, like reference characters or numerals denote like elements, and redundant descriptions thereof will be omitted.

In FIG. 8, the capacitor device 50 may be provided on the substrate 102. The capacitor device 50 may include a first electrode 512, a second electrode 514, the insulating film 116, an upper wiring layer (e.g., 522a and 522b), and a lower wiring layer (e.g., 524a and 524b).

Each of the first electrode 512 and the second electrode 514 may include a first sidewall and a second sidewall opposite the first sidewall. In some implementations, the first sidewall of the first electrode 512 may face a first lower wiring layer 524a and the second sidewall of the first electrode 512 may face a first upper wiring layer 522a. The first sidewall of the second electrode 514 may face a second lower wiring layer 524b and the second sidewall of the second electrode 514 may face a second upper wiring layer 522b.

The first electrode 512 may include a first base portion 512E, which is between the first lower wiring layer 524a and the second lower wiring layer 524b and extends in the vertical direction (the Z direction), and a first pad portion 512P, which extends from the first base portion 512E in the second horizontal direction (the Y direction) and is in contact with the first lower wiring layer 524a. The first pad portion 512P may be between the first lower wiring layer 524a and the second lower wiring layer 524b. The first pad portion 512P may protrude from the first base portion 512E toward the first lower wiring layer 524a. Similar to the first electrode 512, the second electrode 514 may include a second base portion 514E, which is between the first lower wiring layer 524a and the second lower wiring layer 524b and extends in the vertical direction (the Z direction), and a second pad portion 514P, which extends from the second base portion 514E in the second horizontal direction (the Y direction) and is in contact with the second lower wiring layer 524b. The second pad portion 514P may be between the first lower wiring layer 524a and the second lower wiring layer 524b. The second pad portion 514P may protrude from the second base portion 514E toward the second lower wiring layer 524b.

In some implementations, the first lower wiring layer 524a may be in contact with the first pad portion 512P of the first electrode 512, the first upper wiring layer 522a may be in contact with the first base portion 512E of the first electrode 512, the second lower wiring layer 524b may be in contact with the second pad portion 514P of the second electrode 514, and the second upper wiring layer 522b may be in contact with the second base portion 514E of the second electrode 514.

The first lower wiring layer 524a, the second lower wiring layer 524b, and the first upper wiring layer 522a may not overlap the first electrode 512 in the vertical direction (the Z direction). The second upper wiring layer 522b may overlap at least a part of the first pad portion 512P of the first electrode 512 in the vertical direction (the Z direction). The first pad portion 512P of the first electrode 512 may be separated from the second upper wiring layer 522b by a portion of the insulating film 116 in the vertical direction (a +Z direction). The first lower wiring layer 524a, the second lower wiring layer 524b, and the second upper wiring layer 522b may not overlap the second electrode 514 in the vertical direction (the Z direction). The first upper wiring layer 522a may overlap at least a part of the second pad portion 514P of the second electrode 514 in the vertical direction (the Z direction). The second pad portion 514P of the second electrode 514 may be separated from the first upper wiring layer 522a by a portion of the insulating film 116 in the vertical direction (the +Z direction).

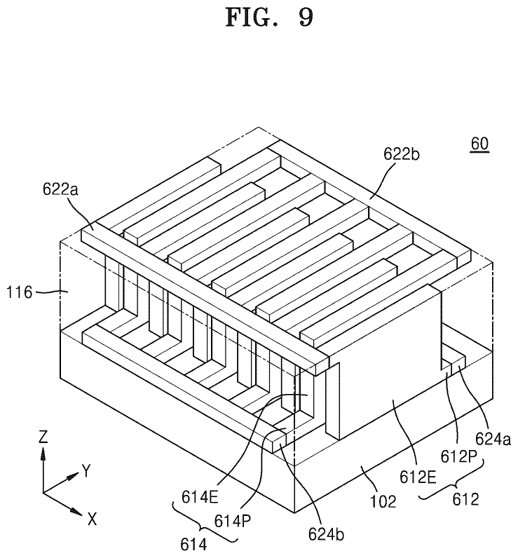

FIG. 9 is a diagram illustrating an example of a capacitor device according to some implementations. In FIG. 9, a capacitor device 60 is configured substantially similar to the capacitor device 10, and the capacitor device 60 is described focusing on the differences from the capacitor device 10. In FIGS. 1 to 4B and FIG. 9, like reference characters or numerals denote like elements, and redundant descriptions thereof will be omitted.

In FIG. 9, the capacitor device 60 may be provided on the substrate 102. The capacitor device 60 may include a first electrode 612, a second electrode 614, the insulating film 116, an upper wiring layer (e.g., 622a and 622b), and a lower wiring layer (e.g., 624a and 624b).

Each of the first electrode 612 and the second electrode 614 may include a first sidewall and a second sidewall opposite the first sidewall. In some implementations, the first sidewall of the first electrode 612 may face a first lower wiring layer 624a and the second sidewall of the first electrode 612 may face a first upper wiring layer 622a. The first sidewall of the second electrode 614 may face a second lower wiring layer 624b and the second sidewall of the second electrode 614 may face a second upper wiring layer 622b.

The first electrode 612 may include a first base portion 612E, which is between the first lower wiring layer 624a and the second lower wiring layer 624b and extends in the vertical direction (the Z direction), and a plurality of first pad portions 612P, which extend from the first base portion 612E in the second horizontal direction (the Y direction) and are respectively in contact with the first upper wiring layer 622a and the first lower wiring layer 624a. The first pad portions 612P may be respectively between the first upper wiring layer 622a and the second upper wiring layer 622b and between the first lower wiring layer 624a and the second lower wiring layer 624b. The first pad portions 612P may protrude from the first base portion 612E respectively toward the first upper wiring layer 622a and the first lower wiring layer 624a. Similar to the first electrode 612, the second electrode 614 may include a second base portion 614E, which is between the first lower wiring layer 624a and the second lower wiring layer 624b and extends in the vertical direction (the Z direction), and a plurality of second pad portions 614P, which extend from the second base portion 614E in the second horizontal direction (the Y direction) and are respectively in contact with the second upper wiring layer 622b and the second lower wiring layer 624b. The second pad portions 614P may be respectively between the first upper wiring layer 622a and the second upper wiring layer 622b and the first lower wiring layer 624a and the second lower wiring layer 624b. The second pad portions 614P may protrude from the second base portion 614E respectively toward the second upper wiring layer 622b and the second lower wiring layer 624b.

In some implementations, the first upper wiring layer 622a and the first lower wiring layer 624a may be respectively in contact with the first pad portions 612P of the first electrode 612, and the second upper wiring layer 622b and the second lower wiring layer 624b may be respectively in contact with the second pad portion 614P of the second electrode 614.

The first upper wiring layer 622a, the second upper wiring layer 622b, the first lower wiring layer 624a, and the second lower wiring layer 624b may not overlap the first electrode 612 in the vertical direction (the Z direction). Each of the first upper wiring layer 622a and the first lower wiring layer 624a may overlap at least a part of one of the second pad portions 614P of the second electrode 614 in the vertical direction (the Z direction). The second pad portions 614P of the second electrode 614 may be separated from the first upper wiring layer 622a and the first lower wiring layer 624a by a portion of the insulating film 116 in the vertical direction (the Z direction and the +Z direction).

In some implementations, the first upper wiring layer 622a, the second upper wiring layer 622b, the first lower wiring layer 624a, and the second lower wiring layer 624b may not overlap the second electrode 614 in the vertical direction (the Z direction) and each of the second upper wiring layer 622b and the second lower wiring layer 624b may overlap at least part of one of the first pad portions 612P of the first electrode 612 in the vertical direction (the Z direction). The first pad portions 612P of the first electrode 612 may be separated from the second upper wiring layer 622b and the second lower wiring layer 624b by a portion of the insulating film 116 in the vertical direction (the +Z direction).

According to some implementations, in the capacitor devices 10, 20, 30, 40, 50, and 60, the first electrodes 112, 412, 512, and 612 may be connected to the first upper wiring layers 122a, 422a, 522a, and 622a, respectively, and to the first lower wiring layers 124a, 424a, 524a, and 624a, respectively, and the second electrodes 114, 414, 514, and 614 may be connected to the second upper wiring layers 122b, 422b, 522b, and 622b, respectively, and to the second lower wiring layers 124b, 424b, 524b, and 624b, respectively. In a comparison example, when a plurality of first electrodes are connected to one of a first upper wiring layer and a first lower wiring layer or a plurality of second electrodes are connected to only one of a second upper wiring layer and a second lower wiring layer, a separate wiring, which is adjacent to the first electrodes and the second electrodes, is required to serve as a route for providing a voltage to each of the first electrodes and the second electrodes. According to some implementations, in the capacitor devices 10, 20, 30, 40, 50, and 60, one of the first upper wiring layers 122a, 422a, 522a, and 622a and the first lower wiring layers 124a, 424a, 524a, and 624a and one of the second upper wiring layers 122b, 422b, 522b, and 622b and the second lower wiring layers 124b, 424b, 524b, and 624b may serve as a route, without the separate wiring described in the comparison example, thereby reducing parasitic capacitance. Accordingly, a capacitor device having improved electrical characteristics may be provided.

According to some implementations, in the capacitor devices 10, 20, 30, 40, 50, and 60, many capacitors may be formed in a unit area and a closed loop may be formed. As a result, a capacitor device having increased capacitance per unit area may be provided.

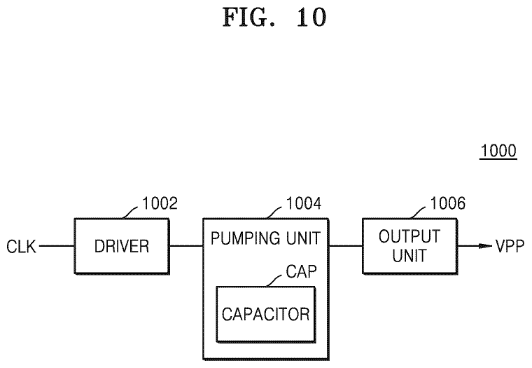

FIG. 10 is a diagram illustrating an example of an operation of a semiconductor device according to some implementations. In FIG. 10, a semiconductor device 1000 may include an internal voltage generation circuit to efficiently use power and may generate various internal voltages by using the internal voltage generation circuit. Examples of the internal voltages may include a core voltage, a peripheral voltage, a pumping voltage VPP, and a substrate vias voltage and may be derived from a power supply voltage and a ground voltage, which are applied from the outside.

The internal voltage generation circuit may include a driver 1002 which receives a clock signal CLK and outputs a drive signal, a pumping unit 1004 which receives the drive signal from the driver 1002 and performs a pumping operation on the drive signal, and an output unit 1006 which outputs the pumping voltage VPP resulting from the pumping operation of the pumping unit 1004. Here, the pumping unit 1004 may include at least one capacitor CAP.

In detail, a circuit (e.g., a pumping voltage generation circuit or a substrate vias voltage generation circuit) may boost or reduce a voltage through the capacitor CAP, thereby generating the pumping voltage VPP or the substrate vias voltage. The capacitor CAP may correspond to one of the capacitor devices 10, 20, 30, 40, 50, and 60 described above. However, each of the capacitor devices 10, 20, 30, 40, 50 and 60 described above may be used as a capacitor in various circuits, besides the pumping voltage generation circuit and the substrate vias voltage generation circuit.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A capacitor device comprising:
a substrate;
a first lower wiring layer and a second lower wiring layer on the substrate;
a plurality of first electrodes on the substrate;
a plurality of second electrodes on the substrate and alternately arranged with the plurality of first electrodes; and
a first upper wiring layer and a second upper wiring layer at a vertical level that is different from a vertical level of the first lower wiring layer and the second lower wiring layer,
wherein the first lower wiring layer is electrically connected to the first upper wiring layer via the plurality of first electrodes,
wherein the second lower wiring layer is electrically connected to the second upper wiring layer via the plurality of second electrodes, and
wherein the first lower wiring layer faces the second lower wiring layer with the plurality of first electrodes and the plurality of second electrodes between the first lower wiring layer and the second lower wiring layer.

2. The capacitor device of claim 1,
wherein the first lower wiring layer, the second lower wiring layer, the first upper wiring layer, and the second upper wiring layer extend in a direction, and
wherein the plurality of first electrodes and the plurality of second electrodes are spaced apart from each other in the direction.

3. The capacitor device of claim 1,
wherein the plurality of first electrodes are arranged between the first lower wiring layer and the first upper wiring layer, and
wherein the plurality of second electrodes are arranged between the second lower wiring layer and the second upper wiring layer.

4. The capacitor device of claim 1, wherein the plurality of first electrodes, the plurality of second electrodes, the first lower wiring layer, the second lower wiring layer, the first upper wiring layer, and the second upper wiring layer define a closed loop.

5. The capacitor device of claim 1, wherein each of the plurality of first electrodes includes:
a first base portion between the first lower wiring layer and the second lower wiring layer, the first base portion extending in a vertical direction; and
a first pad portion extending from the first base portion and in contact with the first upper wiring layer.

6. The capacitor device of claim 1, wherein each of the plurality of first electrodes includes:
a first base portion between the first lower wiring layer and the second lower wiring layer, the first base portion extending in a vertical direction; and
a first pad portion extending from the first base portion and in contact with the first lower wiring layer.

7. The capacitor device of claim 6,
wherein the first upper wiring layer is in contact with the first base portion, and
wherein the second upper wiring layer is separated from the first base portion.

8. The capacitor device of claim 1, wherein each of the plurality of first electrodes includes:
a first base portion between the first lower wiring layer and the second lower wiring layer, the first based portion extending in a vertical direction; and
a plurality of first pad portions extending from the first base portion and respectively in contact with the first lower wiring layer and the first upper wiring layer.

9. The capacitor device of claim 8, wherein each of the plurality of second electrodes includes:
a second base portion between the first lower wiring layer and the second lower wiring layer, the second base portion extending in the vertical direction; and
a plurality of second pad portions extending from the second base portion and respectively in contact with the second lower wiring layer and the second upper wiring layer.

10. The capacitor device of claim 1,
wherein each of the plurality of first electrodes includes:
a first base portion between the first lower wiring layer and the second lower wiring layer, the first base portion extending in a vertical direction; and
a first pad portion extending from the first base portion and in contact with one of the first lower wiring layer and the first upper wiring layer,
wherein the second lower wiring layer and the second upper wiring layer are spaced apart from the first base portion, and
wherein the first pad portion overlaps one of the second lower wiring layer and the second upper wiring layer in the vertical direction.

11. A capacitor device comprising:
a first lower wiring layer and a second lower wiring layer, each extending in a first direction;
a first upper wiring layer and a second upper wiring layer respectively spaced apart from the first lower wiring layer and the second lower wiring layer in a vertical direction;
a plurality of first electrodes, each including a first base portion and a first pad portion, the first base portion being between the first lower wiring layer and the second lower wiring layer and extending in the vertical direction, and the first pad portion protruding from the first base portion toward the first upper wiring layer; and
a plurality of second electrodes, each including a second base portion and a second pad portion, the second base portion being between the first lower wiring layer and the second lower wiring layer and extending in the vertical direction, and the second pad portion protruding from the second base portion toward the second upper wiring layer,
wherein the first lower wiring layer is electrically connected to the first upper wiring layer via the plurality of first electrodes between the first lower wiring layer and the first upper wiring layer, and
wherein the second lower wiring layer is electrically connected to the second upper wiring layer via the plurality of second electrodes between the second lower wiring layer and the second upper wiring layer.

12. The capacitor device of claim 11,
wherein the first lower wiring layer is in contact with the first base portion,
wherein the first upper wiring layer is in contact with the first pad portion,
wherein the second lower wiring layer is in contact with the second base portion, and
wherein the second upper wiring layer is in contact with the second pad portion.

13. The capacitor device of claim 11,
wherein the first lower wiring layer is in contact with the first pad portion, wherein the first upper wiring layer is in contact with the first base portion,
wherein the second lower wiring layer is in contact with the second pad portion, and wherein the second upper wiring layer is in contact with the second base portion.

14. The capacitor device of claim 11,
wherein the first pad portion includes a plurality of first pad portions spaced apart from each other in the vertical direction,
wherein the second pad portion includes a plurality of second pad portions spaced apart from each other in the vertical direction,
wherein the first lower wiring layer and the first upper wiring layer are respectively in contact with the plurality of first pad portions, and
wherein the second lower wiring layer and the second upper wiring layer are respectively in contact with the plurality of second pad portions.

15. The capacitor device of claim 11,
wherein each of the plurality of first electrodes has a first sidewall and a second sidewall opposite the first sidewall,
wherein the first lower wiring layer faces the first sidewall of each of the plurality of first electrodes, and
wherein the first upper wiring layer faces the second sidewall of each of the plurality of first electrodes.

16. A capacitor device comprising:
a lower capacitor structure including a first lower wiring layer and a second lower wiring layer spaced apart from each other and extending in a direction;
a first upper wiring layer and a second upper wiring layer respectively spaced apart from the first lower wiring layer and the second lower wiring layer in a vertical direction, the first upper wiring layer and the second upper wiring layer being spaced apart from each other and extending in the direction;
a plurality of first electrodes electrically connected to the first lower wiring layer and the first upper wiring layer;
a plurality of second electrodes electrically connected to the second lower wiring layer and the second upper wiring layer, and alternately arranged with the plurality of first electrodes in the direction;
an upper capacitor structure including a first lower interlayer wiring layer and a second lower interlayer wiring layer spaced apart from each other, and extending in the direction on the lower capacitor structure;
a first upper interlayer wiring layer and a second upper interlayer wiring layer respectively spaced apart from the first lower interlayer wiring layer and the second lower interlayer wiring layer in the vertical direction, the first upper interlayer wiring layer and the second upper interlayer wiring layer being spaced apart from each other and extending in the direction;
a plurality of third electrodes electrically connected to the first lower interlayer wiring layer and the first upper interlayer wiring layer;
a plurality of fourth electrodes electrically connected to the second lower interlayer wiring layer and the second upper interlayer wiring layer, and alternately arranged with the plurality of third electrodes in the direction; and
an interlayer insulating film between the lower capacitor structure and the upper capacitor structure,
wherein each of the plurality of first electrodes has a first sidewall and a second sidewall opposite the first sidewall,
wherein the first lower wiring layer faces the first sidewall of each of the plurality of first electrodes, and
wherein the first upper wiring layer faces the second sidewall of each of the plurality of first electrodes.

17. The capacitor device of claim 16,
wherein each of the plurality of first electrodes includes:
a first base portion between the first lower wiring layer and the second lower wiring layer, and extending in a vertical direction; and
a first pad portion protruding from a sidewall of the first base portion, and
wherein each of the plurality of third electrodes includes:
a third base portion between the first lower interlayer wiring layer and the second lower interlayer wiring layer, and extending in the vertical direction; and
a third pad portion protruding from a sidewall of the third base portion.

18. The capacitor device of claim 17, wherein the first pad portion overlaps at least a part of the third pad portion in the vertical direction.

19. The capacitor device of claim 17, wherein the first pad portion does not overlap the third pad portion in the vertical direction.

20. The capacitor device of claim 16,
wherein each of the plurality of third electrodes has a first sidewall and a second sidewall opposite the first sidewall,
wherein the first lower interlayer wiring layer faces the first sidewall of each of the plurality of third electrodes, and
wherein the first upper interlayer wiring layer faces the second sidewall of each of the plurality of third electrodes.
